(19) United States
(12) Patent Application Publication
(10) Pub. No.: US 2015/0221363 A1
(43) Pub. Date: Aug. 6, 2015

(54) METHOD FOR CACHE SRAM DATA RETENTION IN SWITCHED OFF POWER SUPPLY MODE GENERATING EXTREMELY SMALL POWER DISSIPATION

(71) Applicant: GORAN KRILIC, ZAGREB (HR)

(72) Inventor: GORAN KRILIC, ZAGREB (HR)

(21) Appl. No.: 14/628,306

(22) Filed: Feb. 23, 2015

Related U.S. Application Data
(63) Continuation-in-part of application No. 13/856,425, filed on Apr. 3, 2013.
(60) Provisional application No. 61/945,224, filed on Feb. 27, 2014.

(51) Int. Cl. G11C 11/412; G11C 5/14; G11C 11/417

(52) U.S. Cl. CPC G11C 11/412; G11C 11/417; G11C 5/148

(57) ABSTRACT

If the power of SRAM is completely switched off including substrate and wells or more precisely if power supply rails are put on ground potential, leakage is non existing but the data is lost. It is however possible that data is retained in power off mode under optical illumination of substrate where parasitic photodiodes connected to charge nodes are operating in photovoltaic mode. Power for data retention is generated by light and there is no power consumption from power supply which is essential for mobile battery operated devices.

### BACKGROUND OF THE INVENTION

This application claims priority of U.S. provisional application No. 61/945,224 filed on Feb. 27, 2014. This application is Continuation-In-Part of pending U.S. application Ser. No. 13/856,425. Application Ser. No. 13/856,425 describes improved leakage reduction methods in CMOS SRAM, embedded SRAM and cache SRAM memories. Improvement is enabled by optical refreshing. Optical refreshing is illumination of chip substrate and generation of photogenerated charge carriers which diffuse to parasitic PN junctions. PN junctions drains of PMOS (or NMOS) transistor—well (or substrate) generate refreshing photocurrents which compensate leakage and retains data on charge nodes. Since substrate or wells are biased on power supply potential, photodiodes are operating in reverse biased photoconductive mode. If the power is completely switched off including substrate and wells or more precisely if power supply rails are put on ground potential leakage is non existing but the data is lost. It is however possible that data is retained in power off mode under optical illumination of substrate but the aforementioned parasitic photodiodes are operating in photovoltaic mode. Power for data retention is generated by light and there is no power consumption from power supply which is essential for mobile battery operated devices. FIG. 7 shows light input in a) flip-chip chip packing, b) wirebond chip packing, figure c) shows transparent lid on the chip. FIG. 4 shows light penetration depth in silicon and FIG. 5 shows diffusion length in Ntype silicon. Silicon substrates have Nd in the area 10E15-10E16 and consequently diffusion lengths of few hundred micrometers. For 600-700 thick chips near infrared light generates diffusion photocurrent in chip's active layer. Light can be applied frontside or backside of the chip.

### Embodiment 1A

Referring to FIG. 3A, in one embodiment, a light source is positioned proximal to the substrate on the substrate side of the memory cell 300. The light source is operatively configured to emit light of a specific spectrum, having a peak wavelength, indicated with words hω (and numbers 301 and 302) and is directed towards the memory cell 300. The spectrum and the peak wavelength of the light source emission are selected to penetrate the substrate an average distance Lₚₑₙ before they get absorbed. Absorption of photons creates electron-hole pairs which are now free to diffuse through the substrate in all directions. A fraction of minority carriers diffuse towards the front of the cell 300 and reach at least the pn-junction D7 between the n-epilayer and the p-well (indicated with 303) and the pn-junction D4 between the p+drain diffusion region of PMOS pass transistor M4 and the n-epilayer (indicated with 304). The figure does not show other pn-junctions that may or may not capture these diffusing minority carriers as they are not fundamental to the operation of the memory cell refreshing. Once the minority carriers reach a pn-junction, they are swept by the built-in electric field and thereby create a DC current; the pn-junction becomes a current source with current directed from the cathode towards the pn-junction anode. Reaching the pn-junction terminates the diffusion of minority carriers as they become majority carriers on the other side of the junction. The magnitude of the generated current equals the current of minority carriers reaching the pn-junction from one side.

The current generated by pn-junction D7 is conducted to ground (GND) terminal (path is shown with 305), hence no diffusion of minority carriers generated in the substrate proceeds within the p-well. The current generated at pn-junction D4 by the arrival of diffusing minority carriers is the useful current that is used to refresh the storage node Q. FIG. 3B illustrates these relationships: pn-junction D7 generates current between the VDD (now on GND) and GND terminals and is hence lost (and not useful). The current generated by pn-junctions D4 and D2 charge the storage nodes thereby accomplish refreshing.

The average distance the minority carriers can diffuse is quantified by their diffusion length L_{diff}. Clearly, if the thickness of the substrate is L_{sub}, for the light source to contribute to the refreshing of the memory cell, we require that L_{sub}˜L_{diff}+L_{abs}. For example, a light-emitting diode with emission centered at 1050 nm and low doped n-type substrate with absorption length of 400 um and diffusion length of 300 um, the substrate thickness may be around 700 um.

FIG. 4 shows publicly available data on the absorptance and penetration depth for light of certain wavelength into silicon. FIG. 5 show publicly available data on the diffusion length in silicon substrates of different doping levels. Typical substrate doping levels are in the 10¹⁵ and 10¹⁶ cm⁻³ range. These graphs support the example mentioned above and are used as further guidance to implement the device and method.

### DESCRIPTION OF THE INVENTION

Article: University of Cambridge, Computer Laboratory, Technical Report No. 536, 2002, Sergei Skorobogatov: “Low temperature data remanence in static RAM” describe measurement on different SRAM chips when they are completely powered off by grounding all nodes. If the chips are switched on in few milisecond time and the data is red out it is proved that data is retained. The explanation is that charge node discharges in a non linear fashion through forward biased PN junction. As voltage on charge node decreases discharging current is getting smaller. In few milisecond voltage is arround few hundred milivolts which is a minimum voltage, data retention voltage, which still saves data in the cell. Bellow that voltage inverters will flip and the data in all cells is lost. Forward current decreases sharply with temperature.

When SRAM chip is totally powered off, by connection of all terminals to GND, including wells and substrate, charge nodes storing logical “0” will retain their state. Charge nodes storing logical “1”, Q on FIG. 1, will start to loose charge (data). Charge node will start to discharge through forward biased PN junctions drain of load PMOS M4 (connected to charge node Q)-N substrate (connected now to GND instead of normally to Vdd), see FIGS. 1 and 2. If the chip is opened to allow optical illumination of the substrate and illuminated backside, see FIG. 3A, photocurrent will flow in a photovoltaic mode. That is under forward bias condition, see FIG. 3B. PN (photo)diode characteristic on FIG. 6, see quadrant IV, shows that photocurent will increase as charge node is being discharged and charge node voltage is decreasing from Vdd towards GND. Forward current, see quadrant I, is a discharging current and it decreases as charge node discharges. At one point, experiments show that at optical power level of 0.7 mW/cm2 it is at about 330 mV, both currents, charging reverse photocurrent and discharging forward curent, will come into equillibrium.

At that point discharging is stoped and voltage level of 330 mV remain on storage node. It is supported by photocurrent generated in photovoltaic (unbiased) mode. Experimental data is shown in article: Sensors 2004, 5, 58-70, “p-n Junction Photocurrent Modelling Evaluation under Optical and Electrical Excitation”, Constantine T. Dervos et. al.

It is also shown that 330 mV is more than data retention voltage (250 mV) DRV including safeguard voltage margin for technology mismatch influence on threshold voltage of transistors and temperature variations. Following article shows measurements of DRV and theoretical calculations
:“SRAM Leakage Suppression by Minimizing Standby Supply Voltage” Huifang Qin et. al. Department of EECS University of California at Berkeley, PPT, ISQED 2004

330 mV is also voltage that is on gate of NMOS driver transistor which drain is connected to oposite storage node Qbar storing logical “0”.Photocurrent is also generated in PN junction PMOS load M2 drain—N substrate on GND (instead of Vdd prior to switch off), see FIGS. 2 and 3B, which charges charge node Qbar storing logical “0”. Threshold voltages of NMOS and PMOS transistors in 65 nm and 45 nm CMOS state of the art commercial technologies are 0.29 V. Thus NMOS driver transistor M1, FIG. 2, connected to storage node Qbar and having gate voltage (330 mV) larger than threshold voltage (290 mV) will keep storage node Qbar firmly clamped to GND. Photocurrent will

be grounded. NMOS driver transistors are much stronger than PMOS load transistors and if photocurrent is adjusted so that the voltages on storage nodes are equal to threshold voltage (290 mV) NMOS driver current will be larger than photocurrent while PMOS load current will be much lower than photocurrent. Thus, storage node Q will remain at 290 mV while storage node Q bar will remain at GND.

Thus, when power is switched on second inverter (M4+M3), see FIG. 2, voltage will be on voltage larger than DRV which is above trip point of first inverter. Thus data will be retained and fully reinstated.

To improve operation and safeguard for technology mismatch of driver and load transistors' threshold voltages, it should be desirable that Vthreshold of PMOS is larger than that of NMOS driver transistors. Since PMOS is not involved in read operation it will not cause performance penalty. On the other hand lower threshold NMOS will improve speed of operation in active mode.

Different modifications of the invention described herein are possible to one skilled in the art. For example p type (n well) substrate silicon CMOS technology can be used for implementation. Different light sources ambient, display backlight, keyboard backlight or dedicated LED attached to chip frontside (wirebond chip packing) or backside (flip-chip packing) can be used. Embedded System on Chip SRAM or caches in multicore microprocessors as well as discrete SRAM chips can be utilised for optical data remanence in power off mode.

### Power Consideration

If the light is sourced from ambient light source, as mobile device keyboard or display backlight, power drawn from Vdd power supply is zero Watts and the information in SRAM (cache) is preserved. Electrical power required for data retention on storage nodes is generated in SRAM chip by light originating from outside source.

If dedicated LED diode is attached to SRAM (microprocessor, ASIC or SoC) chip then LED is connected to SRAM power supply—SRAM is powered down so there is no power dissipation in SRAM. However, LED has to generate 0.7 mW/cm2 to maintain data in SRAM, as described herein. OLED, for example has 99% internal quantum efficiency and 20% external efficiency. Thus power supply is loaded by 3.5 mW/cm2 electrical power. In 65 nm CMOS technology memory cell area is arround 0.5 um2. For 1 Mb SRAM (cache) total cells' area is arround 1 mm2. Thus, required electrical power to maintain data is only 35 uW.

In drowsy caches leakage power is 7 nW/cell or 7 mW for 1 Mb SRAM array. If no leakage reduction is implemented leakage power would be 700 mW which is almost 40% of total cache power (total 2W power) for typical mobile processor, for example Intel Silverthorn (Atom). Thus optical data retention with SRAM chip completely powered down, with LED light source connected to chip Vdd, consumes only 35 uW. It is 200×less than leakage power consumption in drowsy caches.

### FIGURES

FIG. 1—6T SRAM powered—prior art

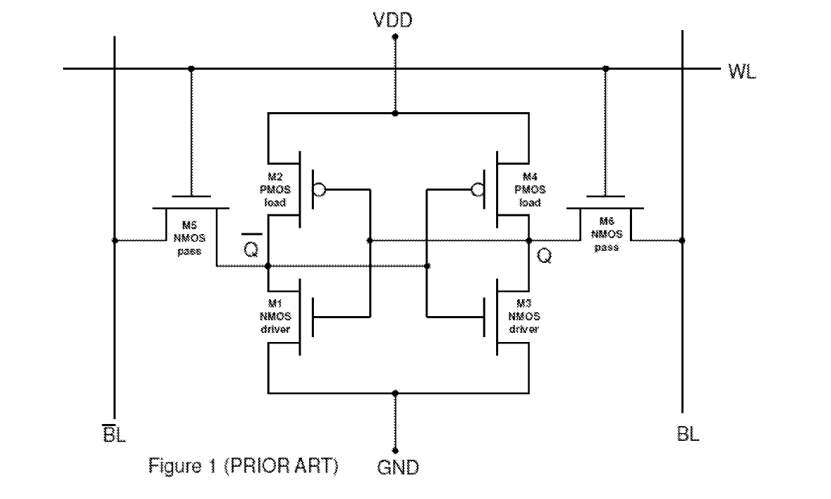

FIG. 2—6T SRAM in power off mode

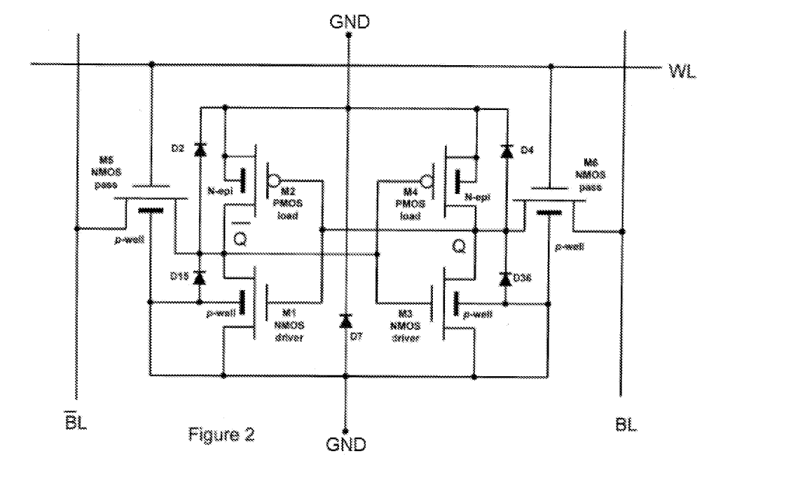

FIG. 3A—illuminated and powered off CMOS 6T SRAM cell cross-section

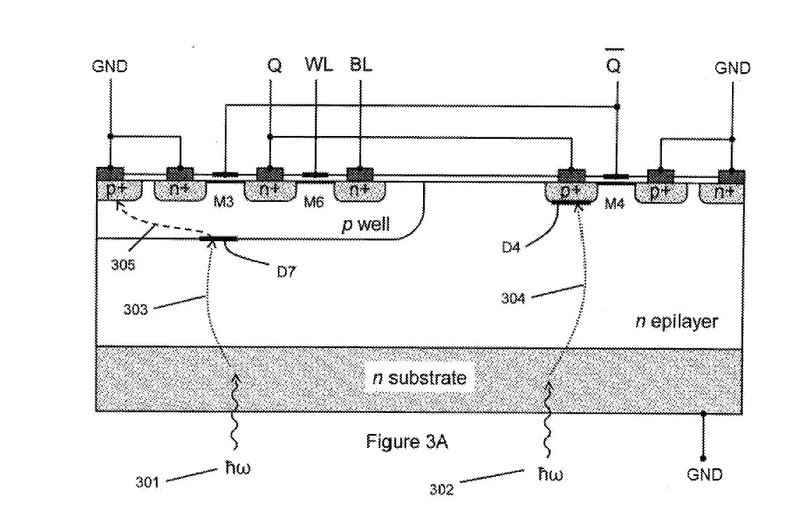

FIG. 3B—illuminated 6T SRAM cell currents in power off mode

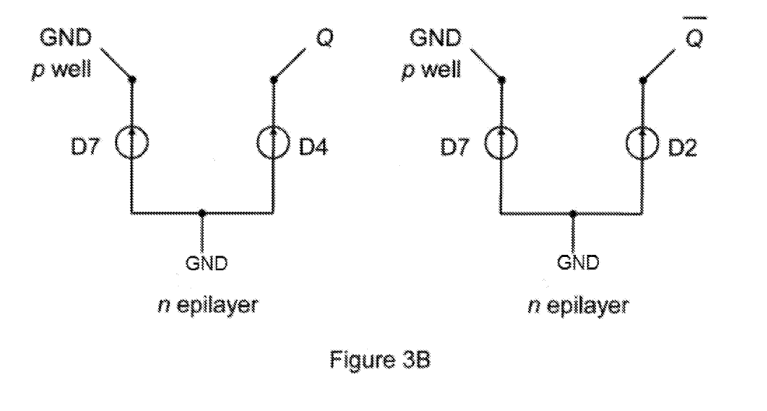

FIG. 4—light penetration depth in silicon

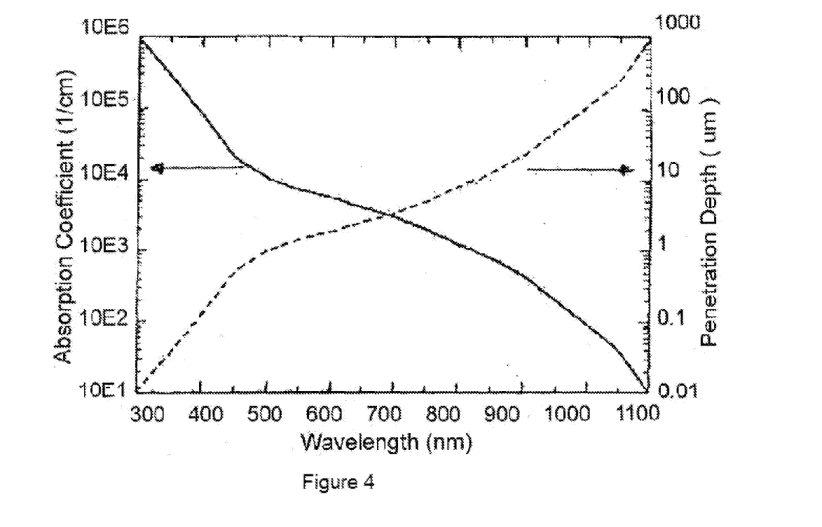

FIG. 5—photogenerated charge carriers' diffusion lengths in N type silicon substrate

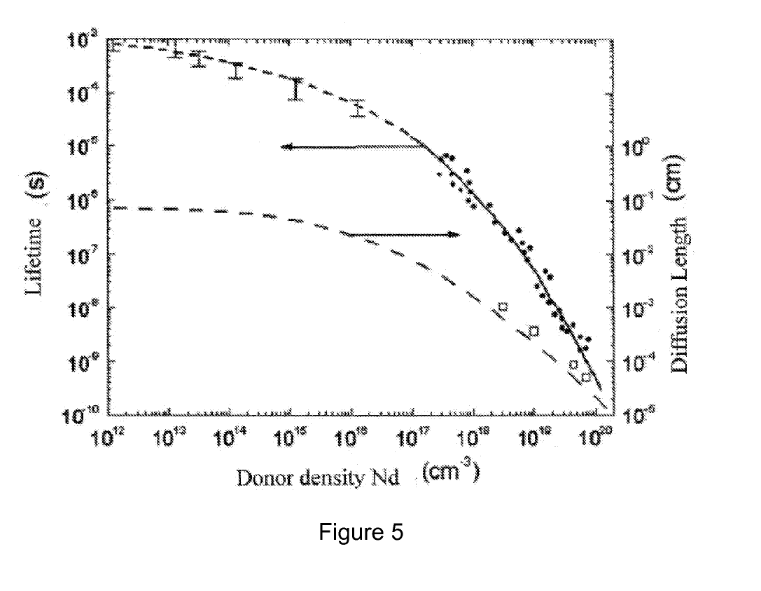

FIG. 6—PN junction current-voltage characteristic in photovoltaic mode

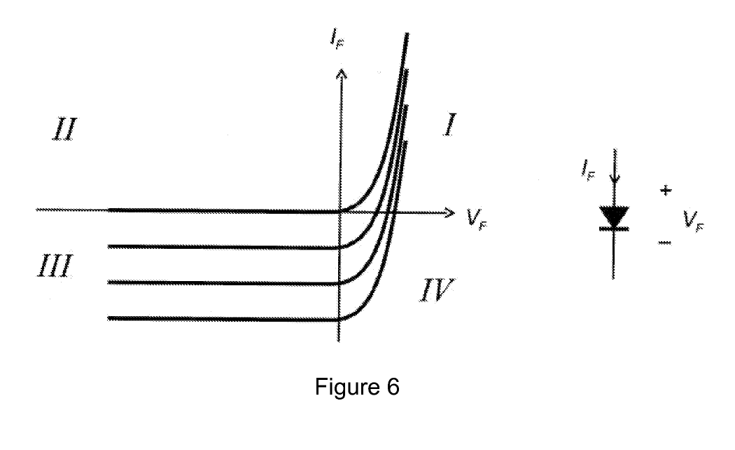

FIG. 7—optical illumination of chips

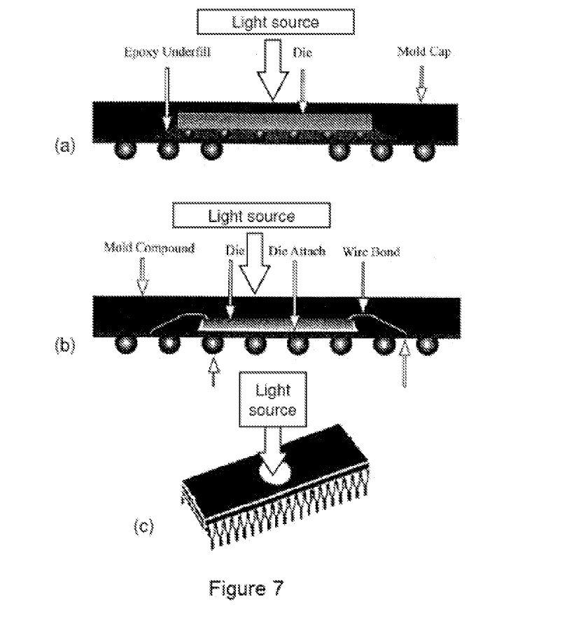

1. A method for refreshing totally powered down static random access memory comprising:
providing at least one six-transistor static random access memory cell disposed on a substrate and comprising two storage nodes, two pass transistors, two load transistors, and two driver transistors, said load transistors having drain diffusion regions forming pnjunctions with said substrate;
and
providing a light source emitting light, a portion of said light being absorbed and converted to minority carriers in said substrate, said minority carriers diffusing through said substrate, a portion of said minority carriers reaching said pn-junction and causing said pn-junction to generate electrical current in a photovoltaic mode;
wherein said electrical current charges said storage nodes
and compensates discharging forward current flowing in photovoltaic mode said electrical current keeping minimum data retention voltage on charge node storing logical one.

2. The method of claim 1, wherein said light source faces said substrate of said memory cell.

3. The method of claim 1, wherein said light source is proximal to said memory cell and distal from said substrate.
